(19) United States
(12) Patent Application Publication
(10) Pub. No.: US 2025/0323065 A1
(43) Pub. Date: Oct. 16, 2025

(54) APPARATUS FOR SEMICONDUCTOR SOLVENT PROCESSING UTILIZED FOR 3D AND TRADITIONAL PROCESS FLOWS

(71) Applicant: VEECO INSTRUMENTS INC., Plainview, NY (US)

(72) Inventors: John Taddei, Marco Island, FL (US); Phillip Tyler, Horsham, PA (US); Kevin Donnelly, Horsham, PA (US); Mark Yannuzzi, Horsham, PA (US); Darrell Kreider, Horsham, PA (US)

(73) Assignee: VEECO INSTRUMENTS INC., Plainview, NY (US)

(21) Appl. No.: 19/171,798

(22) Filed: Apr. 7, 2025

Related U.S. Application Data
(60) Provisional application No. 63/632,745, filed on Apr. 11, 2024.

(51) Int. Cl. H01L 21/67; C11D 7/50; H01L 21/02

(52) U.S. Cl. CPC H01L 21/67051; C11D 7/5009; H01L 21/02057; H01L 21/67057

(57) ABSTRACT

A system and method for removing organic materials from a surface of a substrate are provided, where the organic materials can include photoresist, temporary bonding materials, adhesives, fluxes, and their respective residues. In the system and method, the substrate is immersed in a first fluid in an immersion station. The substrate is transported from the immersion station to a process chamber, where the substrate is sprayed via a high-velocity spray nozzle with a second fluid in the process chamber. The first fluid and the second fluid is incompatible with stainless steel, and the organic materials are removed from the surface of the substrate via the immersion of the substrate in the first fluid and the spraying of the substrate via the second fluid.

### CROSS REFERENCE TO RELATED APPLICATION

The present application claims the benefit of and priority to U.S. patent application Ser. No. 63/632,745, filed Apr. 11, 2024, which is hereby expressly incorporated by reference in its entirety.

### TECHNICAL FIELD

The present disclosure relates to solvent processing for semiconductors, and more specifically, to a system and method that uses solvents or other chemistry that is incompatible with stainless steel to strip organic materials from substrates.

### BACKGROUND

The adoption of 3D packaging to increase semiconductor performance has spawned a variety of enhancements to existing process flows and development of new manufacturing techniques. 3D process flows can incorporate techniques such as bumps, pillars, micro bumps, imbedded bumps and pads to electrically connect vertically stacked devices. These devices can be fabricated on separate substrates and then connected either as individual devices (e.g., die to wafer) or in group (e.g., wafer to wafer, or collective die to wafer).

The manufacturing processes can include many steps that employ organic films for a specific purpose. For example, photoresist can be used to form a mask for partial layer material addition\subtraction (such as bump or pillar formation; or die singulation with plasma dicing). Photoresist exposed to plasma in processes such as plasma dicing can be difficult to remove, as is the debris (in many cases fluorinated debris) that accumulates on unprotected surfaces during the plasma process. Flux is used to prevent oxidation and clean metallic surfaces prior to reflow and bonding. Temporary bonding materials are used to adhere die or whole wafers through one or several steps (for example: grinding for wafer thinning; plasma or mechanical dicing for die singulation; die alignment for bonding). These temporary bonding materials vary widely based on the function they perform—laser release, mechanical release and strength of the bond required. Furthermore, these temporary bonding materials can become more difficult to remove based on the thermal budget of the process flow. The higher the temperature they are exposed to, the more aggressive the process is required to remove them.

Thus, there can be points in the process flow where three or more organic films are on the substrate, and they will need to be stripped via a wet process either individually or collectively. These organic films or materials, such as photoresist, flux, and temporary bonding materials, can have different properties, and thus can be difficult to remove from the substrate all at one once.

Accordingly, there is a need for these organic films to have diverse properties of resistance to chemistries in order to remove one film selectively to another, and there is also a need for more aggressive processes that can remove all of the organic films in their entireties without resorting to extensive processing.

### SUMMARY

In a first aspect, a method for removing organic materials from a surface of a substrate is provided, where the organic materials comprise at least one of photoresist, temporary bonding materials, adhesives, fluxes, and their respective residues. In the method, the substrate is immersed in a first fluid in an immersion station, wherein the first fluid is incompatible with stainless steel. The substrate is then transported from the immersion station to a process chamber. The substrate is then sprayed via a high-velocity spray nozzle with a second fluid in the process chamber, wherein the second fluid is incompatible with stainless steel. The organic materials are removed from the surface of the substrate via the immersion of the substrate in the first fluid and the spraying of the substrate via the second fluid.

In another aspect, the high-velocity spray nozzle is configured such that a spray arm thereof is formed at an angle of 30 degrees or lower relative to a horizontal reference plane for discharging the second fluid towards the substrate.

In another aspect, the method further includes spin drying the one or more substrates to remove remnants of the second fluid from the surface of the substrate.

In another aspect, at least one of the first fluid and the second fluid comprises benzenesulfonic acid.

In another aspect, the method further includes dispensing a low-pressure, heated third fluid on the one or more substrates at the process station, wherein the third fluid replenishes the fluid lost during transport of the substrate from the immersion station.

In another aspect, both the first fluid and the second fluid are the same fluid. In a further aspect, the method further comprises recycling the first fluid from the immersion station and transporting it to the process chamber, wherein the second fluid is the recycled first fluid. In a further aspect, the method includes dispensing a fourth fluid on the substrate at the process station via the high-velocity spray nozzle after spraying with the second fluid, wherein the fourth fluid comprises a fresh fluid that displaces the recycled first fluid on the substrate, and the fourth fluid is incompatible with stainless steel.

In another aspect, the velocity of the spray of the high-velocity spray nozzle is approximately 500-8,000 inches per second.

In another aspect, the distance from high-velocity spray nozzle to the one or more substrates is approximately 0.1 to 2 inches.

In another aspect, the pressure of the second fluid to the high-velocity spray nozzle is approximately 10-100 psi and the pressure of nitrogen to the high-velocity spray nozzle is approximately 10-100 psi.

In a second aspect, a system for removing organic materials from a substrate is provided, where the organic materials comprise at least one of photoresist, temporary bonding materials, adhesives, fluxes, and their respective residues. The system includes an immersion station having an immersion chamber is configured to immerse the substrate in a first fluid, and a nitrogen inlet, wherein introduction of nitrogen into the immersion chamber keep moisture and contaminants out of the immersion chamber to maximize the effectiveness of the first fluid and to prevent corrosion on the substrate, and wherein the first fluid is incompatible with stainless steel. The system also includes a process chamber having a spray arm that comprises a high-velocity spray nozzle, wherein the process chamber is configured to hold the substrate via a chuck, and wherein the high-velocity spray nozzle is configured to spray the substrate with a second fluid, wherein the second fluid is incompatible with stainless steel. The system also includes a transfer arm configured to transport the substrate between stations. The immersion station and process station are configured to remove organic materials from the surfaces of the substrate via immersion in first fluid and spraying of the second fluid, respectively.

In another aspect, the immersion station is comprised of perfluoroalkoxy (PFA), polyetheretherketone (PEEK), polypropylene, or polyvinylidene fluoride (PVDF), or combinations thereof.

In another aspect, the spray arm is configured to form an angle of 30 degrees or lower relative to a horizontal reference plane for discharging the second fluid towards the substrate via the high-velocity spray nozzle.

In another aspect, the chuck of the process chamber is a spin chuck configured to spin the substrate during spraying of the substrate with the second fluid.

In another aspect, the system further includes a spin station comprising a spin chuck, wherein the spin chuck is configured to spin dry the substrate to remove remnants of the second fluid from the surface of the substrate.

In another aspect, at least one of the first fluid and the second fluid comprises benzenesulfonic acid.

In another aspect, both the first fluid and the second fluid are the same fluid.

In another aspect, the system further includes a recycle tank in fluid communication with the immersion station and\or the process station, wherein the recycle tank is configured to receive run-off of the second fluid in the process station, and to transmit the received second fluid back to the process station as recycled fluid, and wherein the second fluid is the recycled fluid. In a further aspect, the high-velocity spray nozzle or a low pressure nozzle of the process chamber are further configured to dispense additional fluid on the substrate at the process station after spraying with the second fluid, wherein the additional fluid comprises a fresh fluid that displaces the recycled fluid on the substrate.

In another aspect, the high-velocity spray nozzle is configured to spray fluid on the one or more substrates at a velocity of approximately 500-8,000 inches per second.

In another aspect, the distance from high-velocity spray nozzle to the substrate is approximately 0.1 to 2 inches.

In another aspect, the high-velocity spray nozzle is configured to accept heated solvent at a pressure of approximately 10-100 PSI and nitrogen at a pressure of approximately 10-100 PSI.

### BRIEF DESCRIPTION OF THE DRAWING FIGURES

FIG. 1 displays a flow diagram of an exemplary method for removing organic materials from a substrate in accordance with one or more embodiments.

FIG. 2 shows an exemplary immersion tooling comprising substrates in accordance with one or more embodiments.

FIGS. 3A-3B show perspective views of an exemplary immersion station in accordance with one or more embodiments.

FIG. 4 is a schematic of the connections of the immersion station of the system in accordance with one or more embodiments.

FIG. 5 is a schematic of the connections of the solvent recycling components of the system in accordance with one or more embodiments.

FIG. 6 is a schematic of the connections of the solvent spray station (process station) of the system in accordance with one or more embodiments.

FIGS. 7A-7C displays a perspective view (7A), a top view (7B), and a cross-sectional view (7C) of a high velocity spray nozzle of the solvent spray station (process station) in accordance with one or more embodiments.

FIG. 8 is a block diagram illustrating an exemplary configuration of an exemplary process controller of the system for removing organic materials in accordance with one or more embodiments.

### DETAILED DESCRIPTION OF CERTAIN EMBODIMENTS

The present application discloses systems and methods for removing organic materials from a substrate. The system can include an immersion station, a solvent spray station (process station), and components for recycling the solvents. In accordance with one or more embodiments, the system can further a spin station. In at least one embodiment, one or more substrates are immersed in a first fluid that is incompatible with stainless steel in the immersion station. The treated substrates are then transported to the process station, where they are sprayed via a high-velocity spray nozzle with a second fluid that is incompatible with stainless steel. Both the first fluid of the immersion station and the high-velocity spray of the second fluid at process station work to remove organic materials, such as photoresist, temporary bonding materials, adhesives, fluxes, and their respective residues, from the surface of the substate. The substrate can then optionally be transported to a spin station dedicated to aid in the drying of the substate.

The present systems and methods allow for a faster and more efficient way of removing organic materials from the substrate as compared with traditional methods, without damaging the substrate or the components of the system. This efficiency stems, in part, from the system utilizing two forms of organic material removal: new chemistries or solvents, which can be used in both of the immersion station and the solvent spray station, as well as the velocity and manner in which the new chemistries dispensed (e.g., high pressure) at the solvent spray station.

Complete stripping of the organic materials (e.g., organic film strip), as measured by traditional methods such as laser defectivity inspection or SEM inspection, are insufficient for hybrid bonding. Hybrid bonding requires a pristine surface for a Cu\Cu bond. Many of these traditional organic film strip processes require an additional chemistry for surface conditioning, in order to lower the contact angle on the surface of the substrate (e.g., wafer, die, etc.).

In contrast, the present systems and methods enable cutting edge 3D technology by using a variety of new chemistries to accomplish selective or entire organic film stripping processes and subsequent surface preparation for bonding. Many of these chemistries are not compatible with stainless steel (e.g., 316 stainless steel [316 SS]). Traditional solvents (e.g., N-methyl-2-pyrrolidone [NMP], dimethyl sulfoxide [DMSO], acetone) have generally been compatible with stainless steel and therefore wet process tools were previously constructed with stainless steel (e.g., 316 SS) as the material for wetted parts, such as chambers, tanks, tubing, dispense arms, nozzles.

However, to accommodate the new chemistries (e.g., solvents) of the present system and method that are not compatible with stainless steel, the various components of the present system, particularly those that come into contact with the various chemistries and solvents, are preferably made of other materials, such as polymers like perfluoroalkoxy (PFA) or high-purity PFA, polyetheretherketone (PEEK), polypropylene, or polyvinylidene fluoride (PVDF), or combinations thereof.

Additionally, in one or more embodiments the high-velocity spray nozzle can dispense solvents/chemistries at a high velocity (eg., 8,000 inches\second, which is >2.5× greater velocity than fluid dispensed from a traditional high pressure pump at 3,000 PSI) to enable physical removal of the organic materials to supplement the chemical removal process that the solvent/chemistries provides. In one or more embodiments, the velocity of the high-velocity spray nozzle has a range of approximately 500-8,000 inches per second. In one or more embodiments, the velocity of the high-velocity spray nozzle has a range of approximately 4,000-8,000 inches per second, 5,000-8,000 inches per second, 6,000-8,000 inches per second, or 7,000-8,000 inches per second. High pressure dispensing provided superior cleaning results and the highest yield, without damage to remaining substrate. In one or more embodiments, the high-velocity spray nozzle is configured to accept heated solvent at a pressure of approximately 10-100 PSI and nitrogen at a pressure of approximately 10-100 PSI.

In conventional systems, cleanliness, solvent chemical resistance, static dissipative properties and the pressures involved required the use of stainless steel in the wetted path. However, in the present systems and methods, the new chemistries require wet process tools to transition to designs without stainless steel components in the wetted path to support the new chemistries, while maintaining the ability to operate in a wide range of aggressiveness of process to ensure complete removal of organic materials and to provide a pristine surface.

These and other aspects of the present systems and methods are described in further detail below. As used in the present application, the term “incompatible with stainless steel” is used in reference to solvents, compounds, or chemistries that are corrosive to stainless steel. Further, as used in the present application, the term “approximately” when used in conjunction with a numerical value refers to any number within about 5, 3 or 1% of the referenced numerical value, including the referenced numerical value.

In accordance with one or more embodiments, the present systems and methods perform semiconductor manufacturing processes utilizing chemistries that are not compatible with stainless steel to remove organic films (such as photoresist, temporary bonding materials, fluxes, or combinations thereof) selectively or in entirety, remove ancillary materials (such as residues from plasma exposure, material lift off surpluses, etc) and\or to prepare substrate surfaces for bonding.

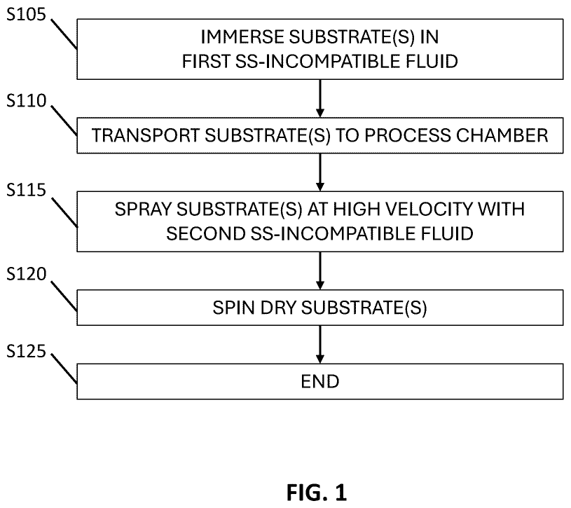

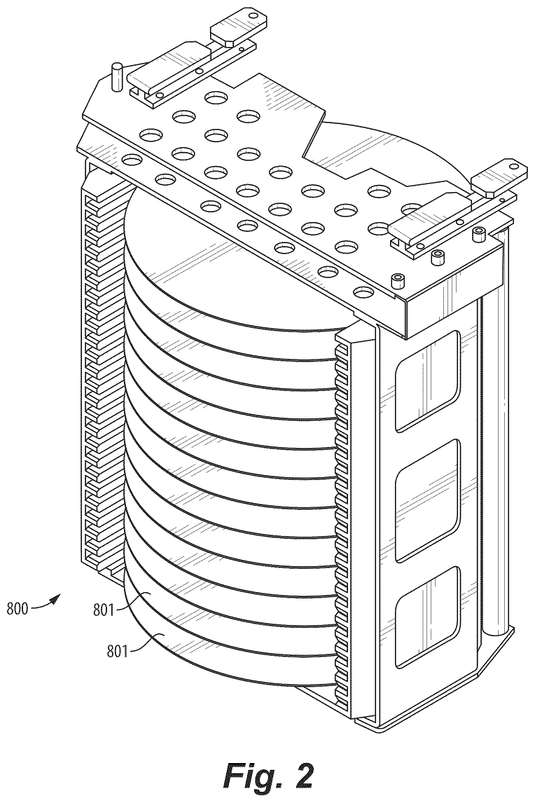

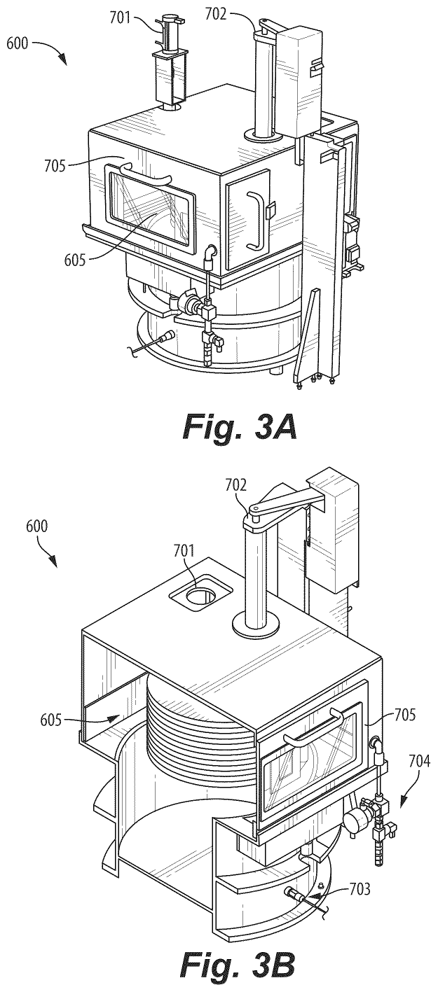

FIG. 1 displays a flow diagram of an exemplary method for removing organic materials from a substrate in accordance with one or more embodiments. The method begins at step S105 where one or more substrates are placed in the immersion station and immersed in a first fluid that is incompatible with stainless steel. For example, a substrate can be withdrawn from an input Front Opening Unified Pod (FOUP)\cassette, for example, and be placed into immersion station tooling that is submerged in the first fluid (chemistry) in the immersion station. In one or more embodiments, the first fluid can comprise benzenesulfonic acid. In one or more embodiments, the first fluid can comprise a photoresist stripper, a residue-removing semiconductor stripper, various sulfur-containing compounds, or acetic acid, or combinations thereof. An exemplary immersion station tooling 800 is shown in FIG. 2, which can contain one or more substrates 801 (e.g., wafers, dies, etc). FIGS. 3A-3B show perspective views of an exemplary immersion station 600 in accordance with one or more embodiments. FIG. 3A shows a perspective view of the immersion station 600 showing the outer doors to the immersion chamber 605, and FIG. 3B shows a perspective view of the immersion station not showing a portion of the outer door to the immersion chamber 605 to better show the interior of the chamber 605. In one or more embodiments, the immersion station 600 is constructed of PFA, PEEK, polypropylene, PVDF, or other suitably chemically resistant plastic or combinations thereof.

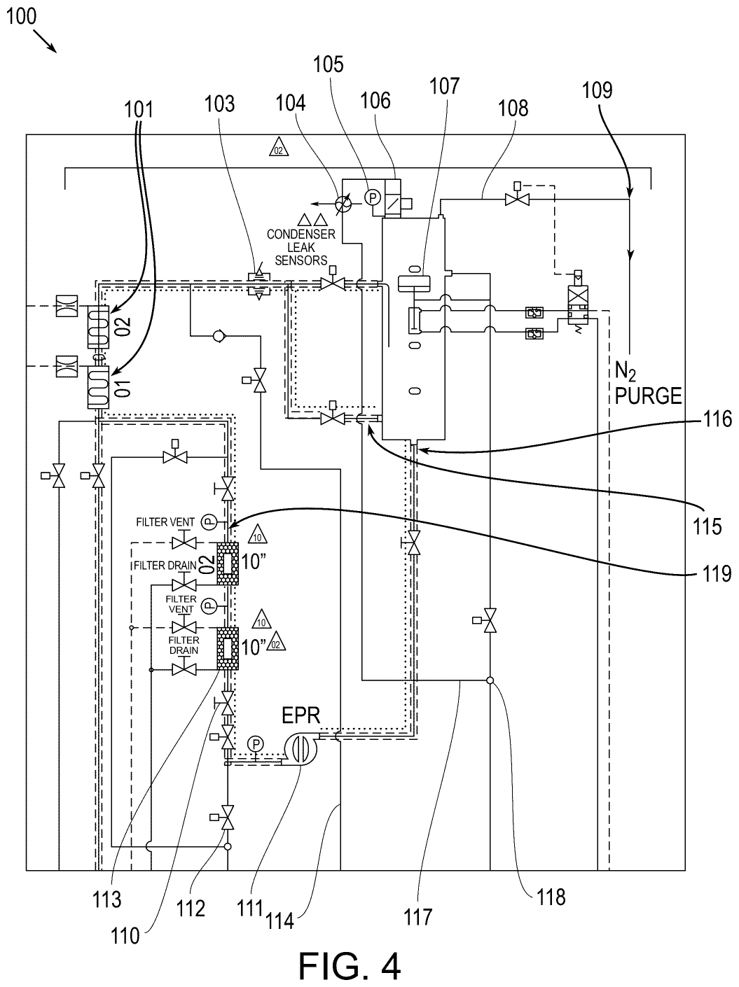

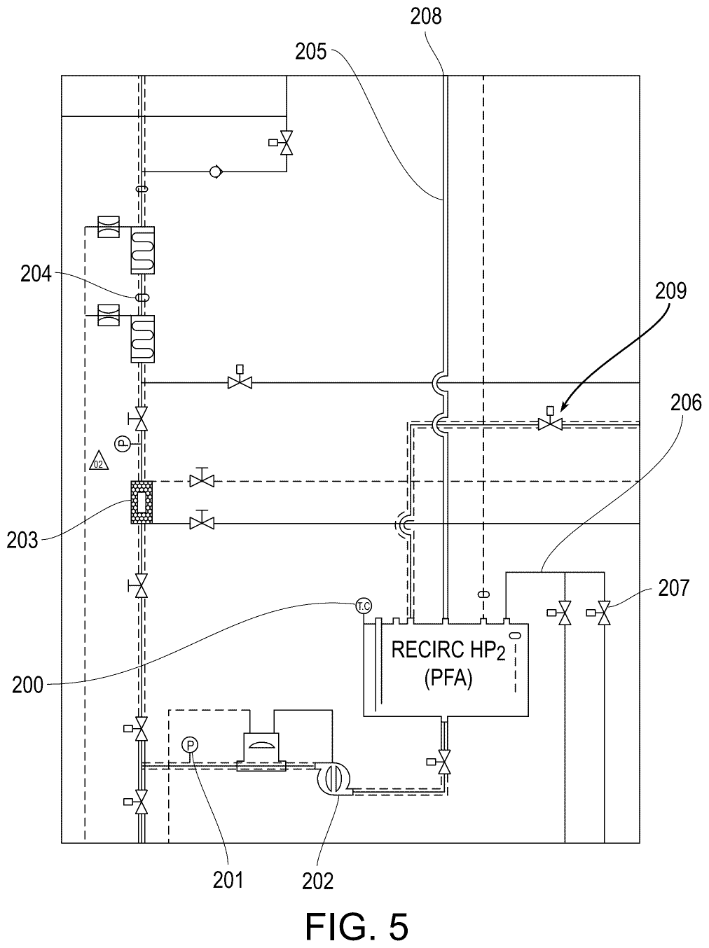

A schematic of the various connections of the immersion station of the present system in accordance with one or more embodiments is shown in FIG. 4. As shown in FIG. 4, in one or more embodiments the immersion station can comprises one or more heaters 101 in a recirculation loop (shown in dotted lines) and they provide the capability to heat the first fluid (chemistry). In one or more embodiments, the heater can be monitored via a thermocouple 102 (703 in FIG. 3B) and regulated to a setpoint that does not exceed a flashpoint of the chemistry (first fluid). In one or more embodiments, the thermocouple 102 can be imbedded in the heater. In certain embodiments, the recirculation loop can be serviced by an adjustable speed pump 111 that can regulate pressure, monitored by a pressure transmitter. In certain embodiments, the recirculation loop can also have one or more manual valves 110 and pneumatic valves 112. In one or more embodiments, one or more filters 113 is also provided to remove semi-dissolved organics or other debris. In at least one embodiment, multiple filters can be utilized in series. For example, 9 μm and 0.1 μm filters can be utilized in series to remove semi-dissolved organics or other debris. In at least one embodiment, dual pressure transmitters 119 can also be included to provide data to software that is used to monitor pressure drop in and to signal when the filters need to be replaced.

With continued reference to FIG. 4, in one or more embodiments the immersion station can further include a non-wetted flowmeter 103 that provides real time feedback for the chemistry (first fluid) pumped through the recirculation loop. In one or more embodiments, the immersion station can comprise an exhaust connection (701 as shown in FIGS. 3A-3B) which can include a condenser 104, a differential pressure indicator 105 and a butterfly valve for exhaust control 106.

Referring now to FIGS. 3A-3B, in one or more embodiments, nitrogen can be introduced into the immersion station via an inlet 704 to keep moisture and contaminants for the fabrication air out of the immersion station for maximize the life of the chemistries and to prevent corrosion on the processed wafers. It is also noted that, in one or more embodiments, the components that are proximate to the immersion station or areas near the immersion station door, (e.g., elevator 702; immersion station tooling 800) are designed and fabricated in materials and designed consistent with periodic exposure to the harsh chemistries and their fumes\vapors. The immersion station 600 can further include a loading door 705 (see FIG. 4, 107) that keeps heat and chemical fumes inside the immersion station when closed and permits wafer exchange when open.

With reference again to FIG. 4, in one or more embodiments the immersion station can further include a nitrogen purge 108 that maintains an inert environment in the immersion station when the door is closed, so that moisture, contaminants, and air do not shorten the life of the chemistry (first fluid). A purge feed 109 can be regulated for pressure and monitored to alarm if proper conditions are not met. Additionally, in at least one embodiment the immersion station can include an additional nitrogen line 114 that has pneumatic and check valves for blowing the recirculation loop free of chemistry for servicing. In at least one embodiment, the immersion station can further include upper and lower recirculation loop inlets 115 and a drain 116. In at least one embodiment, the immersion station has an overflow drain 118 that also services a condenser drain 117.

In one or more embodiments, the immersion station can be configured to control the placement timing for substrates, such as wafers, masks, tape frames, etc, using software, for example. The timing can be set up to maintain specific outcomes.

In one or more embodiments, the immersion station utilizes a chemical-based process to reach a specific point in the process. Accordingly, in such embodiments, the same dwell time must be maintained for all substrates that pass through the station. To accomplish this the time between wafers being input must match the time required for each of the rest of the processing chambers to accomplish their processes. In other words, the time between loading wafers into the immersion station must equal the time required to process wafers in the slowest spin chamber. If these times are equal, the wafers will flow steadily through the tool. If the wafers were loaded at a faster rate than the other chambers can process them, however, wafers would back up in the wet station and some wafers would have a longer immersion time while they wait to be processed in subsequent chambers, which would continue to expose them to the chemistry and have a longer exposure time than the first wafers processed. Many solvents can remove the thin films, such as Cu or Ti, at a slow rate (20 A\min for example), but if a wafer is immersed for an extra 10 minutes, for example, it would lose 200 A of the exposed metal film. This can reduce semiconductor performance, lifetime, or in a worst case, yield. Accordingly, for semiconductor manufacturing it is desirable that all wafers see the same process.

In one or more embodiments, the number of wafer slots used in the immersion cassette (immersion tooling 800—FIG. 2) can be calculated for the immersion step based on an immersion time required and the time required for subsequent steps in the method, which includes the time spent by the substrates (e.g., wafers) at each process step and handling time in between stations. In one or more embodiments, the time of substrate flow through the system can be controlled via software, which can also be used to help track the total time a substrate spends in the immersion station. In at least one embodiment, the system can include a failsafe that will not permit the substrate to be withdrawn from the immersion station until its full process (immersion) time has been reached. This failsafe can be controlled via software, for example.

Depending on the specifics of the particular substrate cleaning process that is being executed, the timing for how long the substrate is in the immersion station and the time for transporting the substrate from the immersion station to the process station can be adjusted based on a number of factors as understood by those of ordinary skill in the art. Exposure time to the first fluid in the immersion station can be varied, but in any case, is sufficient to reach the desired goals of the operator (e.g., swelling or partial dissolving of the organic films) but minimized to ensure maximum throughput of the system and to prevent unintended etching of collateral material (e.g., copper) from exposure to the first fluid.

Returning to FIG. 1, upon reaching the desired wetted time (immersion time), at step S110 the substrate is withdrawn from the immersion station and transferred to the process station (solvent spray station). In one more embodiment, the one or more substrates are transferred between stations of the system via a transfer arm (not shown) configured to hold one or more substrates. For example, in one or more embodiments, substrates are transferred between stations via a handler or automatic robot, that typically has 4 arms. The upper two arms of the handler are for moving dry substrates between stations (“dry in” and “dry out”). The bottom two arms of the handler are for wet transfer (e.g., from the immersion station to solvent spray station and from the solvent spray station to a spin rinse dry station). The handler can include a number of paddle types (e.g., vacuum, edge grip, flip, etc.) to meet the contact area requirements of the process as prescribed by the customer.

In one or more embodiments, the substrate is transferred from the immersion station to the solvent spray station while it includes a meniscus of the first fluid on its surface. Even when optimal time has been reached in the immersion station, the process for fully removing the organic material from the substrate is not complete. For example, if the substrate is withdrawn from the immersion station and simply rinsed free of the first fluid or chemistry, and then dried, the yield would be negatively impacted. This is because immersion-only processes does not sufficiently remove all of the organic film. Specifically, immersion-only processes fail to remove all surplus materials (e.g., metals in a material lift off process), organic debris\residues (e.g., plasma hardened resist or fluorocarbons from via formation), and general debris or contamination on the substrate that should not be there but are inherently present from upstream processing. Accordingly, in the present method, the substrates are transferred from the immersion station to a process station that is an aggressive solvent spray station.

Because the chemistries/solvents of the present application are not compatible with stainless steel (SS) and are not sufficient via immersion alone to remove the organic materials, the present methods and systems incorporate a physical removal step (S115) via the process station (solvent spray station). This physical removal step, however, still derives the chemical benefit of the SS-incompatible solvents by utilizing these solvents as the spraying medium. In one or more embodiments, solvents or chemistry from the immersion station can be recycled and used as the spraying medium in the process station.

For example, FIG. 5 shows a schematic of the solvent recycling components of the system in accordance with one or more embodiments. As shown in FIG. 5, recirculated chemistry (e.g., solvent) can originate from the recycle tank 200, which is constructed of PFA, PEEK, polypropylene, PVDF, a combination thereof, or other chemically resistant material, for example. In one or more embodiments, the recycle tank 200 connects to the immersion station via recycle drain 208. The chemistry/solvent can be moved via a controllable pump 202 via pressure that is maintained at the pressure transducer 201. Additionally, in one or more embodiments, the recycled chemistry can be filtered via one or more filters 203 (e.g., 100 nm filters) to maintain a level of cleanliness in the recycled chemistry. The recycling components can further include one or more heaters 204 (e.g., teflon heaters) configured to heat the chemistry up to the temperature desired for processing. In one or more embodiments, the chemistry can be heated to the lower of: a) the flashpoint of the chemistry or b) 120° C., which is the limit of the FEP tubing through which the heated chemistry passes. The temperature can be a recipe setpoint. In one or more embodiments, during idle periods, the flow of the chemistry (e.g., solvent) can be directed through a bypass valve 209 back to the recycle tank 200 after passing through the heater(s) 204 in order to maintain flow and temperature stability.

As discussed above and as shown in FIG. 1, at step S115 at the process station the substrate is sprayed with an SS-incompatible fluid or solvent (chemistry) at a high-velocity to facilitate physical remove of organic material from the surface of the substrate. In one or more embodiments, the process station includes a solvent spray chamber. Returning again to FIG. 5, during the high-velocity spraying step at the process station, chemistry/solvent that is sprayed inside the solvent spray chamber can be returned to the recycle tank 200 via the chamber drain line 205. Additionally, in one or more embodiments, there is one or more recycle tank fill lines 206 for fresh chemical/solvent, and rinsing fluid 207, such as deionized (DI) water. In one or more embodiments, the recycle tank 200 is in fluid communication with the immersion station and the process station, and the recycled fluid loops are generally separate between the immersion station and the solvent spray station. In other words, in one or more embodiments, the immersion tank has a closed loop bypass for filtering, re-heating and re-introduction of recycled chemistry to the immersion station, and similarly the solvent spray station fluid is captured into the recycle tank and then brough back into the spray chamber. The recycle tank 200 can be configured to receive run-off of the second fluid in the process station, and then transmit the received second fluid back to the process station as recycled fluid. In certain embodiments, some or all of the chemistry/solvent utilized in the process station is recycled fluid. In one or more embodiments, the second fluid can comprise benzenesulfonic acid. In one or more embodiments, the second fluid can comprise a photoresist stripper, a residue-removing semiconductor stripper, various sulfur-containing compounds, or acetic acid, or combinations thereof.

In one or more embodiments, all piping, fittings and instrumentation are made of chemically compatible materials (i.e., not made of stainless steel or other materials susceptible to corrosion via the chemistries of the present application).

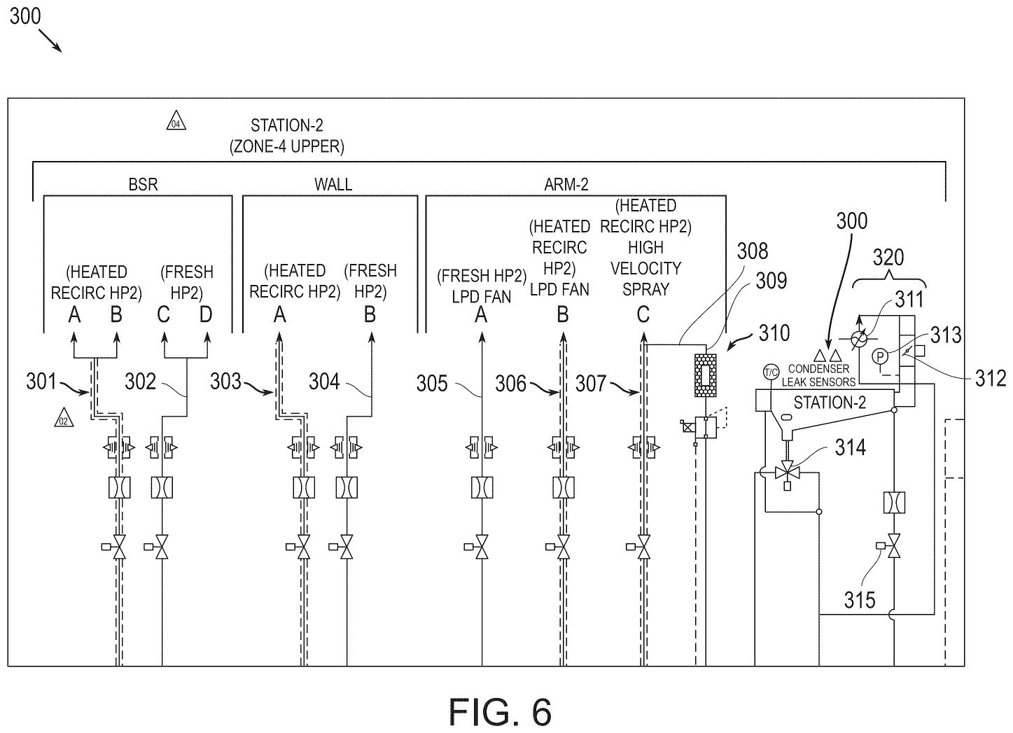

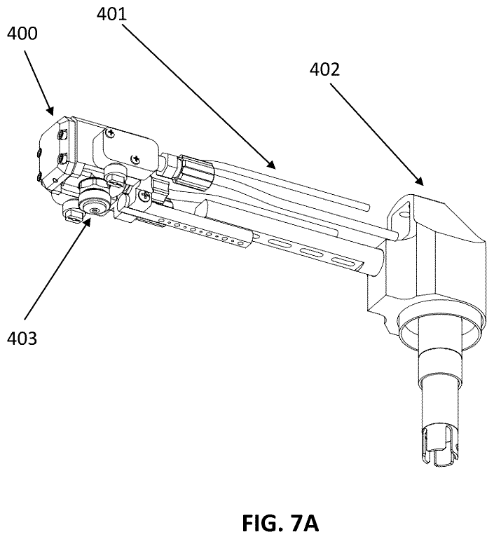

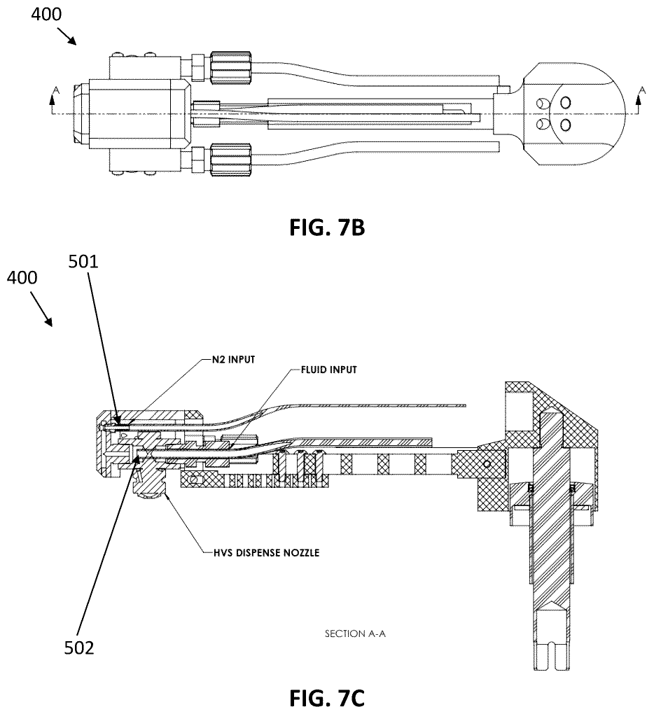

FIG. 6 illustrates a schematic of the connections of the solvent spray station (process station) 300 of the system in accordance with one or more embodiments. In one or more embodiments, nitrogen is used to accelerate the heated chemistry 307 to reach the spray station 300. The heated chemistry is dispensed aggressively using a high velocity spray nozzle 309 (shown as 400 in FIGS. 7A-7C). In one or more embodiments, the pressure and velocity of the spray is controlled via the pressure of the nitrogen (N₂). In one or more embodiments, the N₂ can go through an electronic pressure regulator or mass flow controller 310 and is passed through a filter 309 (e.g., 30 nm filter) and then flows through the N₂ inlet tube 308. The clean, heated, point of use filtered chemistry is accelerated through the high velocity nozzle by the clean, pressure-controlled, point of use filtered N₂. In one or more embodiments, the relative pressures and nozzle types of the process station 300 can be adjusted to obtain a desired flow rate, droplet size, droplet velocity and forces required to accomplish the desired material removal, while minimizing time and collateral material loss, and while inducing no damage or contamination to the substrate surfaces. Since the expansion of N₂ through a nozzle will be subject to the Joules-Thompson effect, in one or more embodiments an N₂ pre-heater (not shown) can be integrated into the process station 300. The heat from the pre-heater can be used to either offset or surpass the cooling from the expanding nitrogen gas through the nozzle.

Although the primary manner in which the process station removes organic material from the substrate is via physical removal via the high-velocity spray of the fluid/solvent, any newly exposed organic material from the physical removal of debris will be subjected to a collateral chemical process from the fluid/solvent. Chemical reaction rates are a function of temperature, so in one or more embodiments heating the fluid/solvent to a high temperature is desirable. The effectiveness of the solvent at dissolving an organic material is generally proportional to the temperature but for safety reasons the solvent is never heated above its flashpoint. While the high-velocity of the spray is the workhorse for the removal of organic materials (e.g., residues and metals) that does not come off the substrate surface via immersion alone, there are benefits to having other dispense types to compliment the high velocity spray. For example, with continued reference to FIG. 6, in at least one embodiment a low pressure, heated solvent dispense 306 can also be used to replenish the fluid lost from the meniscus of fluid during wafer transport. This low-pressure, heated solvent can be dispensed on the substrate to replenish the meniscus before or after spraying with the high-velocity spray. In one or more embodiments, the low pressure solvent dispense 306 typically shares the dispense arm of the HVS dispense 307. Similarly, in at least one embodiment, fresh chemical dispense from an arm 305 can be applied to the substrate at the end the spray process step to displace any recycle chemistry, as the fresh chemistry has fewer particulates than the recycle chemistry.

With continued reference to FIG. 6, in one or more embodiments, the process station 300 can include stationary wall dispenses for fresh 304 and recycle 303 chemistries, which can be used for a final rinse without compromise from droplets falling off an arm dispense. In one or more embodiments, the chemistry/solvent for the fixed and arm based dispenses of the process station is the same as the chemistry/solvent in the immersion station. However, in at least one embodiment, the process chamber can support dispensing of alternate chemistries not used in the immersion station (not shown). As is known and understood in the art, additional hardware and software controls are used in such embodiments to support a multi-chemistry solvent spray (process) chamber. For example, in such embodiments with multiple chemistries in the process chamber, automated chamber purges, drain diverters, collections cups and a host of interlocks within the control system are needed for safe and effective operation. Additionally, the plumbing system is expanded in such embodiments to support additional chemistries.

Referring again to FIG. 6, in one or more embodiments, the process station 300 can further include fresh 302 and recycle 301 backside dispenses, which are configured to rinse the substrate backside free of contamination in similar fashion to the wall operations that spray on the substrate's topside. These rinse chemistries can be dispensed via the high-velocity nozzle, or alternatively via a low pressure dispense. The rinse chemistries do not share plumbing components with the solvent and therefore can have dedicated wetted paths up to being dispensed upon the substrate (e.g., wafer).

In one or more embodiments, all of these operations can be carried out in the process chamber 310, which can be constructed of HALAR® ECTFE (high performance semi-crystalline fluoropolymers) or other chemically resistant material. The chamber 310 can also include an exhaust 320 with a condenser 311. The exhaust 320 can include a butterfly valve 312 for flow control and a differential pressure transducer 313. In one or more embodiments, the drain of the chamber can have a diverter 314 to direct chemistry back to a recycle conduit or drain. In at least one embodiment, the only fluid dispensed in the solvent spray chamber 310 will be the SS-incompatible chemistry of the present application. Accordingly, in such embodiments, all fluid will be directed back to the recycle tank, unless the system is being drained of chemicals for a specific purpose, such as chemical change or maintenance. In at least one embodiment, the chamber 310 can also include a nitrogen purge 315 that is controlled and filtered.

FIGS. 7A-7C displays a perspective view (7A), a top view (7B), and a cross-sectional view (7C) of a high velocity spray nozzle 400 of the solvent spray station (process station) in accordance with one or more embodiments. The high velocity spray nozzle 400 is designed to provide an aggressive physical spray to dislodge and remove materials. As exemplified in FIGS. 7A, in one or more embodiments, the nozzle 400 is attached to a spray arm 401 that can be, in certain embodiments, driven by a stepper motor with a high accuracy encoder. The stepper motor and the arm 401 can be connected through the arm mount 402. In one or more embodiments, the arm 401 is designed for minimum backlash in operation.

With reference to FIG. 7C, in one or more embodiments, filtered, pressurized, and heated recycle (or fresh) chemistry flows into the nozzle 400 through the inlet orifice 502. As shown in FIG. 7C, filtered, pressurized, heated N₂ flows into the high velocity nozzle through the N₂ orifice 501. The inlet orifice 502 and N₂ orifice 501 can be sized relative to each other to deliver a target range of spray volume and other desired droplet properties (e.g., size, velocity, etc).

Referring again to FIG. 7A, in at least one embodiment the nozzle 400 includes a nozzle head 403 that is sized and shaped to dispense the spray to the substrate in one or more desired shapes (e.g., cone, fan, flat, etc.) and a desired spray volume. The dispense of the chemistry flow expands as it leaves the nozzle tip 403. It should be noted that in at least one embodiment, software can be used to control the total force of the spray applied to the substrate surface and in certain embodiments, the total force of the spray applied to the substrate is equal to the force generated at the nozzle tip. However, the expanding spray of chemistry from the high velocity nozzle will contact a larger area of the substrate as the distance from the nozzle tip to the substrate surface is extended. In one or more embodiments, the distance from high-velocity spray nozzle to the one or more substrates is approximately 0.1 to 2 inches. Similarly, when the nozzle dispenses the chemistry at an angle (such as 30 degrees from vertical), the effective force on the substrate will be reduced from the angle of incidence. While the effective force is reduced, there are advantages to an angled dispense of the chemistry from the nozzle, for instance the ability to spray under chiplets or other structures that would block vertical flow, or utilizing a more advantageous contact angle to dislodge adhered debris from the substrate.

In at least one embodiment, the high velocity spray nozzle 400 is mounted on a moving arm (spray arm). In one or more embodiments, the high-velocity spray nozzle 400 is configured such that the spray arm is formed at an angle of 30 degrees or lower relative to a horizontal reference plane for discharging the fluid/solvent towards the substrate. In one or more embodiments, the arm and high velocity spray nozzle are used in conjunction with a spin chuck (not shown) that rotates the substrates as the high velocity spray nozzle applies chemistry to the substrate. The use of the spin chuck allows for the contact of the aggressive spray of chemistry at a variety of angles for each location on the substrate. As would be understood by one of ordinary skill in the art, however, in certain implementations of the present system and method, the use of a fixed arm position or linear or hyperbolic motions of high velocity dispense nozzle can also be advantageous. Likewise a nozzle beneath the substrate (e.g., wafer) facing upward can be included in the process station to provide the benefit of cleaning the downward facing side of the substrate.

Returning again to FIG. 1, after chemistry has been applied to the substrate via the high-velocity spray nozzle, at step S120 the substrate can optionally be spin dried to dry the substrate and remove any leftover chemistry and/or debris from the surface of the substrate. In one or more embodiments, the spin drying can performed by the spin chuck at the process station, or alternatively the substrate can be transported to a separate station comprising a spin chuck to spin dry the substrate. At step S125, the method ends.

Accordingly, the present systems and methods provide numerous advantages over existing methods. For example, the present systems and methods allow for the removal of organic materials from multiple substrates at one time, thereby boosting the throughput of the system. Additionally, the combination of organic material removal at the immersion station (via immersion in chemistry) and the process station (via high-velocity spray) allows for more complete removal of the unwanted organic materials from the surfaces of the substrate. Further, the aggressive spraying of the chemistry at the process station also shortens solvent exposure time so there is less material loss, and chemistry life is extended through chemical (immersion) plus physical removal (high-velocity spray) portions of process.

The solvent processing system for removing organic materials disclosed herein is preferably part of or integrated with a computer implemented system, which can be configured with one or more processors, memory, a controller, and a display, for example to process data received from connected devices into visual information.

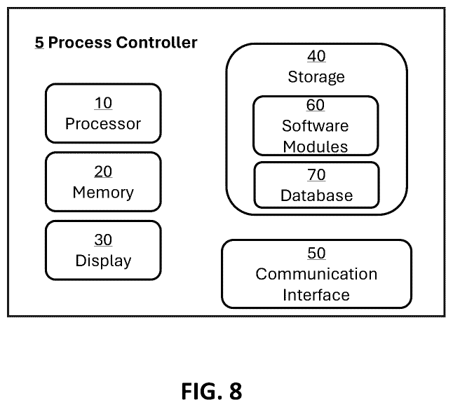

FIG. 8 is a block diagram illustrating an exemplary configuration of an exemplary process controller 5 of the system for removing organic materials in accordance with one or more embodiments. Process controller 5 includes various hardware and software components that serve to enable operation of the system, including a processor 10, memory 20, display 30, storage 40 and a communication interface 50. Processor 10 serves to execute software instructions that can be loaded into memory 20. Processor 10 can be a number of processors, a multi-processor core, or some other type of processor, depending on the particular implementation.

Preferably, memory 20 and/or storage 40 are accessible by processor 10, thereby enabling processor to receive and execute instructions stored on memory and/or on storage. Memory can be, for example, a random access memory (RAM) or any other suitable volatile or non-volatile computer readable storage medium. In addition, memory can be fixed or removable. Storage 40 can take various forms, depending on the particular implementation. For example, storage can contain one or more components or devices such as a hard drive, a flash memory, a rewritable optical disk, a rewritable magnetic tape, or some combination of the above. Storage also can be fixed or removable.

One or more software modules, generally indicated at 60, can be encoded in storage 40 and/or in memory 20. The software modules can comprise one or more software programs or applications having computer program code or a set of instructions executed in processor 10. Such computer program code or instructions for carrying out operations for aspects of the systems and methods disclosed herein and can be written in any combination of one or more programming languages. The program code can execute entirely on process controller, as a stand-alone software package, partly on process controller, or entirely on another computing/device or partly on another remote computing/device. In the latter scenario, the remote computing device can be connected to process controller through any type of direct electronic connection or network, including a local area network (LAN) or a wide area network (WAN), or the connection can be made to an external computer (for example, through the Internet using an Internet Service Provider).

For example, included among the software modules can be a pressure drop module that receives and processes the data from the pressure transmitters 119 to monitor pressure drop in and to signal when the filters need to be replaced. Other modules can be provided to perform the functions described herein, such as substrate flow control, substrate processing; solvent spray control, including controlling the total force of spray; a user interface module; etc. that are executed by processor 10. During execution of the software modules, the processor configures the process controller to perform various operations relating to the system for performing a wet etching process, as will be described in greater detail below.

It can also be said that the program code of software modules and one or more computer readable storage devices (such as memory and/or storage) form a computer program product that can be manufactured and/or distributed in accordance with the present invention, as is known to those of ordinary skill in the art.

It should be understood that in some illustrative embodiments, one or more of software modules can be downloaded over a network to storage from another device or system via communication interface for use within the system. In addition, it should be noted that other information and/or data relevant to the operation of the present systems and methods (such as database) can also be stored on storage, as will be discussed in greater detail below.

Also preferably stored on storage is database 70. As will be described in greater detail below, database contains and/or maintains various data items and elements that are utilized throughout the various operations of the system. The information stored in database can include but is not limited to, parameter adjustment algorithms, recipes, chemical mixture details, set-points, settings, alarms, actual values for process variables, and historical data collected and analyzed by the process controller as will be described in greater detail herein. It should be noted that although database is depicted as being configured locally to process controller in certain implementations database and/or various of the data elements stored therein can be located remotely (such as on a remote computing device or server—not shown) and connected to process controller through a network or in a manner known to those of ordinary skill in the art.

The interface is also operatively connected to the processor. The interface can be one or more input device(s) such as switch(es), button(s), key(s), a touch-screen, microphone, etc. as would be understood in the art of electronic computing devices. Interface serves to facilitate the capture of commands from the user such as on-off commands or settings related to operation of the system.

The display 30 is also operatively connected to processor. Display 30 includes a screen or any other such presentation device which enables the user to view information relating to operation of the system including control settings, command prompts and data collected by various components of the system and provided to process controller. By way of further example, interface and display can be integrated into a touch screen display. Accordingly, the screen is used to show a graphical user interface, which can display various data and provide “forms” that include fields that allow for the entry of information by the user. Touching the touch screen at locations corresponding to the display of a graphical user interface allows the person to interact with the device to enter data, change settings, control functions, etc. So, when the touch screen is touched, interface communicates this change to processor, and settings can be changed or user entered information can be captured and stored in the memory.

Communication interface 50 is also operatively connected to the processor and can be any interface that enables communication between the process controller and external devices, machines and/or elements including [robot, imaging device, etch controller, clean controller, chemistry controller]. Preferably, communication interface includes, but is not limited to, Ethernet, IEEE 1394, parallel, PS/2, Serial, USB, VGA, DVI, SCSI, HDMI, a Network Interface Card (NIC), an integrated network interface, a radio frequency transmitter/receiver (e.g., Bluetooth, cellular, NFC), a satellite communication transmitter/receiver, an infrared port, and/or any other such interfaces for connecting process controller to other computing devices and/or communication networks such as private networks and the Internet. Such connections can include a wired connection (e.g., using the RS232 standard) or a wireless connection (e.g., using the 802.11 standard) though it should be understood that communication interface can be practically any interface that enables communication to/from the process controller.

The processor(s) can be configured, for example, by executing instructions stored on non-transitory processor readable media, to process information of various types and from various sources, including live visual data and data provided via one or more of ablation sensors, instrument controllers, and display(s). In one or more embodiments, the one or more processors can be configured by executing instructions, for example, provided in a series of software and/or hardware modules, to interpret, manipulate and record visual information received from the treatment site. Moreover, the processors can be configured to manipulate and provide illustrative and graphical overlays, and generate composite or hybrid visual data to the display device. The ablation system can further include haptic technology that provides vibratory or other feedback in response to information processed by one or more processors. For example, as described herein, a display provides a graphical representation of an impedance indicator, as a sum of electrode inputs. In addition to a visual, graphical representation, the ablation system can include a catheter configured to provide haptic feedback that corresponds to the visual impedance representation. Thus, the ablation system can include multiple information provisioning, including visual and physical feedback and substantially in real-time.

It is to be understood that the figures and descriptions of the present invention have been simplified to illustrate elements that are relevant for a clear understanding of the present invention, while eliminating, for the purposes of clarity, many other elements which may be 10 found in the present invention. Those of ordinary skill in the pertinent art will recognize that other elements are desirable and/or required in order to implement the present invention. However, because such elements are well known in the art, and because such elements do not facilitate a better understanding of the present invention, a discussion of such elements is not provided herein.

What is claimed is:

1. A method for removing organic materials from a surface of a substrate wherein the organic materials comprise at least one of photoresist, temporary bonding materials, adhesives, fluxes, and their respective residues, the method comprising:
immersing the substrate in a first fluid in an immersion station, wherein the first fluid is incompatible with stainless steel;
transporting the substrate from the immersion station to a process chamber; and
spraying the substrate via a high-velocity spray nozzle with a second fluid in the process chamber, wherein the second fluid is incompatible with stainless steel,
wherein the organic materials are removed from the surface of the substrate via the immersion of the substrate in the first fluid and the spraying of the substrate via the second fluid.

2. The method of claim 1, wherein the high-velocity spray nozzle is configured such that a spray arm thereof is formed at an angle of 30 degrees or lower relative to a horizontal reference plane for discharging the second fluid towards the substrate.

3. The method of claim 1, further comprising:
spin drying the one or more substrates to remove remnants of the second fluid from the surface of the substrate.

4. The method of claim 1, wherein at least one of the first fluid and the second fluid comprises benzenesulfonic acid.

5. The method of claim 1, further comprising:
dispensing a low-pressure, heated third fluid on the one or more substrates at the process station, wherein the third fluid replenishes the fluid lost during transport of the substrate from the immersion station.

6. The method of claim 1, wherein both the first fluid and the second fluid are the same fluid.

7. The method of claim 6, further comprising:
recycling the first fluid from the immersion station and transporting it to the process chamber, wherein the second fluid is the recycled first fluid.

8. The method of claim 7, further comprising
dispensing a fourth fluid on the substrate at the process station via the high-velocity spray nozzle after spraying with the second fluid, wherein the fourth fluid comprises a fresh fluid that displaces the recycled first fluid on the substrate, and the fourth fluid is incompatible with stainless steel.

9. The method of claim 1, wherein the velocity of the spray of the high-velocity spray nozzle is approximately 500-8,000 inches per second.

10. The method of claim 1, wherein the distance from high-velocity spray nozzle to the one or more substrates is approximately 0.1 to 2 inches.

11. The method of claim 1, wherein the pressure of the second fluid to the high-velocity spray nozzle is approximately 10-100 psi and the pressure of nitrogen to the high-velocity spray nozzle is approximately 10-100 psi.

12. A system for removing organic materials from a substrate wherein the organic materials comprise at least one of photoresist, temporary bonding materials, adhesives, fluxes, and their respective residues, the system comprising:
an immersion station having an immersion chamber is configured to immerse the substrate in a first fluid, and a nitrogen inlet, wherein introduction of nitrogen into the immersion chamber keep moisture and contaminants out of the immersion chamber to maximize the effectiveness of the first fluid and to prevent corrosion on the substrate, and wherein the first fluid is incompatible with stainless steel;
a process chamber having a spray arm that comprises a high-velocity spray nozzle, wherein the process chamber is configured to hold the substrate via a chuck, and wherein the high-velocity spray nozzle is configured to spray the substrate with a second fluid, wherein the second fluid is incompatible with stainless steel; and
a transfer arm configured to transport the substrate between stations,
wherein the immersion station and process station are configured to remove organic materials from the surfaces of the substrate via immersion in first fluid and spraying of the second fluid, respectively.

13. The system of claim 12, wherein the immersion station is comprised of perfluoroalkoxy (PFA), polyetheretherketone (PEEK), polypropylene, or polyvinylidene fluoride (PVDF), or combinations thereof.

14. The system of claim 12, wherein the spray arm is configured to form an angle of 30 degrees or lower relative to a horizontal reference plane for discharging the second fluid towards the substrate via the high-velocity spray nozzle.

15. The system of claim 12, wherein the chuck of the process chamber is a spin chuck configured to spin the substrate during spraying of the substrate with the second fluid.

16. The system of claim 12, further comprising:
a spin station comprising a spin chuck, wherein the spin chuck is configured to spin dry the substrate to remove remnants of the second fluid from the surface of the substrate.

17. The system of claim 14, further comprising:
a recycle tank in fluid communication with the immersion station and\or the process station, wherein the recycle tank is configured to receive run-off of the second fluid in the process station, and to transmit the received second fluid back to the process station as recycled fluid, and wherein the second fluid is the recycled fluid.

18. The system of claim 17, wherein the high-velocity spray nozzle or a low pressure nozzle of the process chamber are further configured to dispense additional fluid on the substrate at the process station after spraying with the second fluid, wherein the additional fluid comprises a fresh fluid that displaces the recycled fluid on the substrate.

19. The system of claim 12, wherein the high-velocity spray nozzle is configured to spray fluid on the one or more substrates at a velocity of approximately 500-8,000 inches per second.

20. The system of claim 12, wherein the high-velocity spray nozzle is configured to accept heated solvent at a pressure of approximately 10-100 PSI and nitrogen at a pressure of approximately 10-100 PSI.
